(19) United States
(12) Patent Application Publication
(10) Pub. No.: US 2026/0059961 A1
(43) Pub. Date: Feb. 26, 2026

(54) DISPLAY DEVICE

(71) Applicant: Samsung Display Co., Ltd., Yongin-si (KR)

(72) Inventors: Jeong Ki KIM, Yongin-si (KR); Jang-Il KIM, Yongin-si (KR); Jong-Hoon KIM, Yongin-si (KR); Kyoung Hae MIN, Yongin-si (KR); Keun Chan OH, Yongin-si (KR); Seong Yeon LEE, Yongin-si (KR); Seok-Joon HONG, Yongin-si (KR); Tae Hyung HWANG, Yongin-si (KR)

(21) Appl. No.: 19/169,887

(22) Filed: Apr. 3, 2025

(30) Foreign Application Priority Data
Aug. 22, 2024 (KR) 10-2024-0112881

(51) Int. Cl. H10K 59/38; H10K 59/122; H10K 59/35; H10K 59/80; H10K 102/00

(52) U.S. Cl. CPC H10K 59/38; H10K 59/122; H10K 59/352; H10K 59/873; H10K 59/877; H10K 2102/331

(57) ABSTRACT

A display device includes: a display panel including a first pixel, a second pixel, and a third pixel, wherein the first pixel includes a first light emitting region, the second pixel includes a second light emitting region, the third pixel includes a third light emitting region, the second light emitting region has a chamfered rectangular shape having a pair of long sides extending in a first direction and a pair of short sides extending in a second direction, the long side includes a first side defining the second light emitting region and a second side which is virtually chamfered, the short side includes a third side defining the second light emitting region and a fourth side which is virtually chamfered, and a length of the fourth side is longer than a length of the second side.

### CROSS-REFERENCE TO RELATED APPLICATION

The present application claims priority to and the benefit of Korean Patent Application No. 10-2024-0112881, filed on Aug. 22, 2024, in the Korean Intellectual Property Office, the entire disclosure of which is incorporated herein by reference.

### BACKGROUND

### 1. Field

Aspects of some embodiments of the present disclosure relate to a display device.

### 2. Description of the Related Art

As display devices, light emitting display devices that include images by controlling the brightness of light emitting elements and liquid crystal display devices that display images by controlling the transmittance of a liquid crystal layer are widely used. Unlike liquid crystal display devices, light emitting display devices do not require a separate light source such as a backlight, which allows the display device to be reduced in thickness and weight. In addition, the light emitting display device exhibits high-quality characteristics such as low power consumption, high brightness, and high response speed.

Recently, display devices including a color conversion unit have been proposed to reduce light loss and implement display devices with high color reproducibility. The color conversion unit may include color conversion layers having quantum dots dispersed therein, and may convert incident light into different colors.

The above information disclosed in this Background section is only for enhancement of understanding of the background and therefore the information discussed in this Background section does not necessarily constitute prior art.

### SUMMARY

Aspects of some embodiments of the present disclosure relate to a display device, and for example, to a light emitting display device including a color conversion unit.

Aspects of some embodiments may include a display device including a color conversion unit capable of relatively improving reflectivity.

A display device according to some embodiments includes a display panel including a first pixel, a second pixel, and a third pixel, wherein the first pixel includes a first light emitting region, the second pixel includes a second light emitting region, the third pixel includes a third light emitting region, the second light emitting region has a chamfered rectangular shape having a pair of long sides extending in a first direction and a pair of short sides extending in a second direction, the long sides includes a first side defining the second light emitting region and a second side which is virtually chamfered, the short sides includes a third side defining the second light emitting region and a fourth side which is virtually chamfered, and a length of the fourth side is longer than a length of the second side.

According to some embodiments, the first light emitting region may have a chamfered square shape having a pair of sides extending in the first direction and a pair of sides extending in the second direction, and an angle between a chamfered corner and the side extending in the first direction may be 45 degrees.

According to some embodiments, the display panel may further include a substrate, a first transistor, a second transistor and a third transistor positioned on the substrate, a planarization layer positioned on the first transistor, the second transistor and the third transistor, pixel electrodes positioned on the planarization layer and connected to each of the first transistor, the second transistor and the third transistor, a pixel defining layer positioned on the planarization layer and having a plurality of pixel openings overlapping the pixel electrodes, a light emitting layer positioned on the pixel electrodes and the pixel defining layer and in contact with the pixel electrodes through the pixel openings, a common electrode positioned on the light emitting layer, a first encapsulation layer positioned on the common electrode, a bank positioned on the first encapsulation layer and including a plurality of bank openings, and a first color conversion layer, a second color conversion layer, and a transparent layer individually positioned within the plurality of bank openings.

According to some embodiments, the first color conversion layer and the second color conversion layer may include quantum dots and scatterers, and the transparent layer may include scatterers.

According to some embodiments, the bank opening may overlap the pixel opening.

According to some embodiments, the first color conversion layer may overlap the pixel electrode connected to the first transistor, the second color conversion layer may overlap the pixel electrode connected to the second transistor, and the transparent layer may overlap the pixel electrode connected to the third transistor.

According to some embodiments, the display panel may further comprise a second encapsulation layer positioned on the bank, the first color conversion layer, the second color conversion layer and the transparent layer, and a first color filter, a second color filter, a third color filter, a light blocking region and a plurality of filter openings positioned on the second encapsulation layer.

According to some embodiments, the second encapsulation layer may include a low-refractive index layer.

According to some embodiments, the light blocking region may be positioned at a boundary between the first pixel, the second pixel and the third pixel, and may overlap with the bank and the pixel defining layer.

According to some embodiments, each of the plurality of filter openings may define the first light emitting region, the second light emitting region, and the third light emitting region, and the first color filter, the second color filter, and the third color filter may be each individually positioned within the plurality of filter openings.

According to some embodiments, the light blocking region may be formed by overlapping the first color filter, the second color filter, and the third color filter.

According to some embodiments, the first color filter may overlap the first color conversion layer, the second color filter may overlap the second color conversion layer, and the third color filter may overlap the transparent layer.

According to some embodiments, the filter opening may overlap the bank opening.

According to some embodiments, a width of the bank opening may be wider than a width of the filter opening, and the width of the filter opening may be wider than a width of the pixel opening.

According to some embodiments, the second pixel may include the pixel opening having a rectangular shape having a pair of long sides extending in the first direction and a pair of short sides extending in the second direction.

According to some embodiments, the first pixel may include the pixel opening having a square shape having a pair of sides extending in the first direction and a pair of sides extending in the second direction.

According to some embodiments, the reflectivity of the display device may be relatively improved. Additionally, according to some embodiments, there are additional characteristics that may be recognized throughout the specification.

### BRIEF DESCRIPTION OF THE DRAWINGS

FIG. 1 is a schematic plan view of a display device according to some embodiments.

FIG. 2 is a circuit diagram of one pixel of a display device according to some embodiments.

FIG. 3 is a schematic plan view of a display area in a display panel according to some embodiments.

FIG. 4 is a cross-sectional view taken along the line A-A′ in FIG. 3.

FIG. 5 is a schematic plan view of a display area in a display panel according to some embodiments.

FIGS. 6 and 7 are graphs showing the reflectance improvement effect per 1% of luminous efficiency of a display device according to some embodiments and a display device according to some embodiments.

FIG. 8 is a graph showing a change in reflectivity according to a decrease in the aperture ratio of the field aperture of a display device according to some embodiments.

FIG. 9 is a graph showing luminous efficiency according to a decrease in the reflectivity of a display device according to some embodiments.

FIG. 10 is a block diagram of an electronic device according to some embodiments.

FIGS. 11 to 13 are schematic diagrams of electronic devices according to some embodiments.

### DETAILED DESCRIPTION

Hereinafter, various embodiments of the present disclosure will be described in detail with reference to the attached drawings so that a person having ordinary skill in the art to which the present disclosure pertains may easily implement the disclosure. The present disclosure may be embodied in many different forms and is not limited to the embodiments described herein.

In order to clearly explain the present disclosure, parts irrelevant to the description are omitted, and the same reference numerals are used for identical or similar components throughout the specification.

In addition, the size and thickness of each component shown in the drawings are arbitrarily shown for convenience of explanation, so the present disclosure is not necessarily limited to that which is shown. In the drawings, the thicknesses of layers, films, panels, regions, etc., are exaggerated for clarity. And in the drawings, for convenience of explanation, the thickness of some layers and areas is exaggerated.

Also, when reference is made to a part, such as a layer, membrane, region, or plate, being “over” or “on” another part, this includes not only cases where it is “directly over” the other part, but also cases where there are other parts in between. In contrast, when an element is referred to as being “directly on” another element, there are no intervening elements present. Also, being “above” or “on” a reference part means being located above or below the reference part, and does not necessarily mean being located “above”or “on”it in the direction opposite to gravity.

Additionally, throughout the specification, whenever a part is said to “include” a component, this does not mean that it excludes other components, but rather that it may include other components, unless otherwise specifically stated.

Additionally, throughout the specification, when reference is made to “in a plan view,” it means when the target portion is viewed from above, and when reference is made to “in a cross-section,” it means when the target portion is viewed from the side in a cross-section cut vertically.

Additionally, in the drawings, the symbols “x,” “y,” and “z” are used to indicate directions, where “x” is a first direction, “y” is a second direction perpendicular to the first direction, and “z” is a third direction perpendicular to the first and second directions. The first direction x, the second direction y, and the third direction z may correspond to the horizontal direction, the vertical direction, and the thickness direction of the display device, respectively.

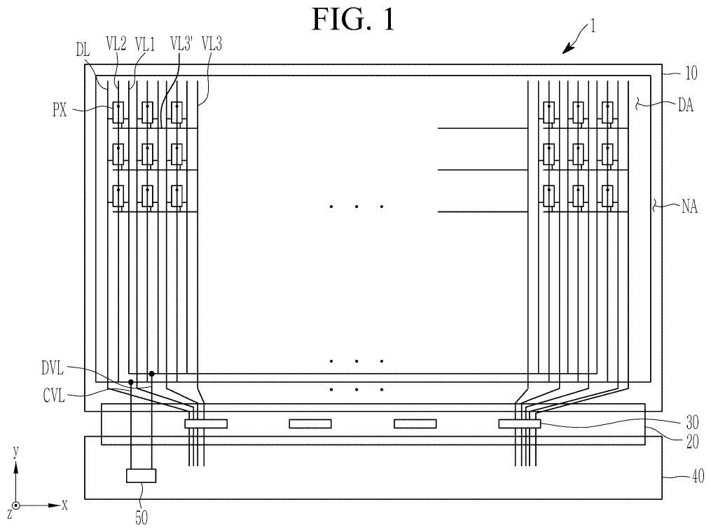

FIG. 1 is a schematic plan view of a display device according to some embodiments.

Referring to FIG. 1, the display device 1 may include a display panel 10, a flexible printed circuit film 20, a driving integrated circuit chip 30, a printed circuit board 40, a power module 50, etc.

The display panel 10 may include a display area DA corresponding to a screen that displays an image, and a non-display area NA in which circuits and/or wires for generating and/or transmitting various signals applied to the display area DA are arranged. The non-display area NA may be adjacent to (e.g., in a periphery or outside a footprint of) the display area DA and may surround the display area DA. In FIG. 1, the inner and outer areas of the dotted rectangle may be the display area DA and the non-display area NA, respectively.

A plurality of pixels PX may be arranged in a matrix in the display area DA of the display panel 10. Additionally, a data line DL transmitting a data voltage VDATA, a driving voltage line VL1 transmitting a driving voltage ELVDD, a common voltage line VL2 transmitting a common voltage ELVSS, and an initialization voltage line VL3 transmitting an initialization voltage VINT may be positioned in the display area DA.

The driving voltage line VL1, the common voltage line VL2, and the initialization voltage line VL3 may extend in the second direction y. The initialization voltage line VL3 may include a branch voltage line VL3′ extending in the first direction x. Each pixel PX may receive the data voltage VDATA, the driving voltage ELVDD, the common voltage ELVSS, and the initialization voltage VINT from these wires. The driving voltage ELVDD and common voltage ELVSS are power voltages applied to each pixel PX, and the driving voltage line VL1 and common voltage line VL2 that transmit these power voltages may be referred to as power voltage lines. The driving voltage ELVDD may be a higher voltage than the common voltage ELVSS. The driving voltage ELVDD may be called a first power supply voltage or a high-potential power supply voltage. The common voltage ELVSS may be called a secondary power voltage or a low-potential power voltage.

A gate driver may be located in the non-display area NA of the display panel 10. The gate driver may be located on either side of the display area DA. The gate driver may be integrated into the non-display area NA. Pixels PX may receive a gate signal (also called a scan signal) generated from a gate driver and receive the data voltage VDATA at a timing (e.g., a set or predetermined timing).

A driving voltage transmission line DVL connected to the driving voltage lines VL1, a common voltage transmission line CVL connected to the common voltage lines VL2, etc. may be located in the non-display area NA of the display panel 10. The driving voltage transmission line DVL and the common voltage transmission line CVL may each include portions extending approximately in the second direction y and portions extending approximately in the first direction x. The common voltage line CVL may be positioned to surround the display area DA. Common voltage lines VL2 may be connected to common voltage transmission lines CVL at the lower and upper sides of the display area DA, thereby supplying a common voltage uniformly across the entire display area DA.

The flexible printed circuit film 20 may have one end connected or bonded to the display panel 10, and the other end connected or bonded to the printed circuit board 40. The driving integrated circuit chip 30 including a data driving unit (or data driver) that applies the data voltage VDATA to the data line DL may be positioned on the flexible printed circuit film 20.

The power module 50 that generates a power voltage such as the driving voltage ELVDD and the common voltage ELVSS may be located on the printed circuit board 40. The power module 50 may be provided in the form of an integrated circuit chip. A signal control unit (or signal controller) that controls the data driving unit (or data driver) and the gate driving unit (or gate driver) may be located on the printed circuit board 40.

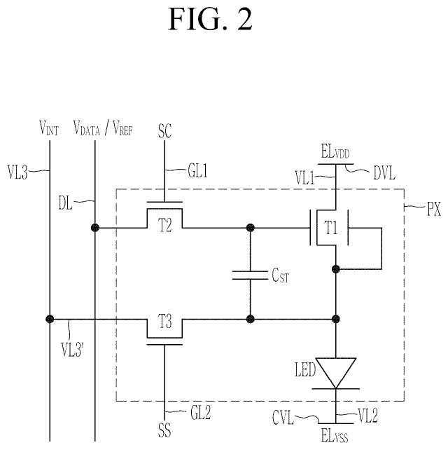

FIG. 2 is a circuit diagram of one pixel of a display device according to some embodiments. Although FIG. 2 illustrates various components in a pixel according to some embodiments, the pixel may include additional components or fewer components without departing from the spirit and scope of embodiments according to the present disclosure.

Referring to FIG. 2, one pixel PX may include first to third transistors T1-T3, a storage capacitor CST, and a light emitting diode LED. The light emitting diodes LED may be an organic diode or an inorganic diode. The first to third transistors T1-T3 may be n-type transistors, and at least some of them may be p-type transistors.

A gate electrode of the first transistor T1 may be connected to a first electrode of the storage capacitor CST. A first electrode of the first transistor T1 may be connected to the driving voltage line VL1 that transmits the driving voltage ELVDD, and a second electrode of the first transistor T1 may be connected to an anode of the light emitting diode LED and a second electrode of the storage capacitor CST. The first transistor T1 may receive the data voltage VDATA according to a switching operation of the second transistor T2 and supply a driving current to the light emitting diode LED according to the voltage stored in the storage capacitor CST.

A gate electrode of the second transistor T2 may be connected to the first gate line GL1 that transmits a first scan signal SC. A first electrode of the second transistor T2 may be connected to the data line DL capable of transmitting the data voltage VDATA or a reference voltage. The second electrode of the second transistor T2 may be connected to the first electrode of the storage capacitor CST and the gate electrode of the first transistor T1. The second transistor T2 may be turned on according to the first scan signal SC to transmit the reference voltage or the data voltage VDATA to the gate electrode of the first transistor T1.

A gate electrode of the third transistor T3 may be connected to a second gate line GL2 that transmits a second scan signal SS. A first electrode of the third transistor T3 may be connected to the second electrode of the storage capacitor CST, the second electrode of the first transistor T1, and the anode. A second electrode of the third transistor T3 may be connected to the initialization voltage line VL3 that transmits the initialization voltage VINT. The third transistor T3 may be turned on in response to the second scan signal SS to transmit the initialization voltage VINT to the anode to initialize the voltage of the anode.

The first electrode of the storage capacitor CST may be connected to the gate electrode of the first transistor T1, and the second electrode of the storage capacitor CST may be connected to the first electrode and an anode of the third transistor T3. A cathode of the light emitting diode LED may be connected to the common voltage line VL2 that carries the common voltage ELVSS. Each light emitting diode LED may constitute one pixel PX, and the anode and the cathode of the light emitting diode LED may be called the pixel electrode and the common electrode, respectively.

The light emitting diode LED may emit light with a brightness (grayscale) depending on the driving current generated by the first transistor T1.

An example of an operation of the circuit illustrated in FIG. 2, particularly the operation during one frame, will be described by taking in the case where all transistors T1-T3 are n-type channel transistors.

When a frame starts, a high-level first scan signal SC and a high-level second scan signal SS are supplied in the initialization section, so that the second transistor T2 and the third transistor T3 may be turned on. According to some embodiments, the reference voltage VREF from the data line DL may be supplied to the gate electrode of the first transistor T1 and the first electrode of a storage capacitor CST through the turned-on second transistor T2, and the initialization voltage VINT may be supplied to the second electrode and the anode of the first transistor T1 through the turned-on third transistor T3. Accordingly, during the initialization period, the anode may be initialized to the initialization voltage VINT. The voltage difference between the reference voltage VREF and the initialization voltage VINT may be stored in the storage capacitor CST.

Next, when the level of the second scan signal SS becomes low while the first scan signal SC is maintained at a high level in a sensing section, the second transistor T2 may be maintained in a turned-on state and the third transistor T3 may be turned off. Through the turned-on second transistor T2, the gate electrode of the first transistor and the first electrode of the storage capacitor CST may maintain the reference voltage, and through the turned-off third transistor T3, the second electrode and the anode of the first transistor may be disconnected from the initialization voltage VINT. Accordingly, when current flows from the first electrode of the first transistor T1 to the second electrode and the voltage of the second electrode becomes a “reference voltage-threshold voltage,” the first transistor T1 may be turned off. Here, a threshold voltage is the threshold voltage of the first transistor T1. At this time, the voltage difference between the gate electrode and the second electrode of the first transistor T1 may be stored in the storage capacitor CST, and sensing of the threshold voltage of the first transistor T1 may be completed. By generating a compensated data signal that reflects a characteristic information sensed during a sensing period, it may be possible to compensate for a characteristic deviation of the first transistor T1 that may differ for each pixel PX.

Next, when the high-level first scan signal SC is supplied and the low-level second scan signal SS is supplied in the data input section, the second transistor T2 may be turned on and the third transistor T3 may be turned off. The data voltage VDATA from the data line DL may be supplied to the gate electrode of the first transistor T1 and the first electrode of the storage capacitor CST through the turned-on second transistor T2. The data voltage VDATA may have a compensated value based on sensing of the threshold voltage of the first transistor T1, thereby compensating for characteristic deviation of the first transistor T1. When the data voltage VDATA is applied, the second electrode and the anode of the first transistor T1 may maintain the potential in the sensing section almost unchanged due to the first transistor T1 being turned off.

Next, the first transistor T1 turned on by the data voltage VDATA transmitted to the gate electrode of the first transistor in the light emitting section may generate a driving current according to the data voltage VDATA, and the light emitting diode LED may emit light by the driving current. That is, the brightness of the light emitting diode LED may be controlled by controlling the driving current applied to the light emitting diode LED according to the size of the data voltage VDATA applied to the pixel PX.

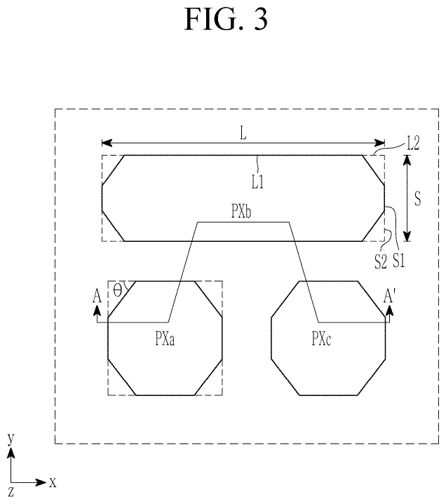

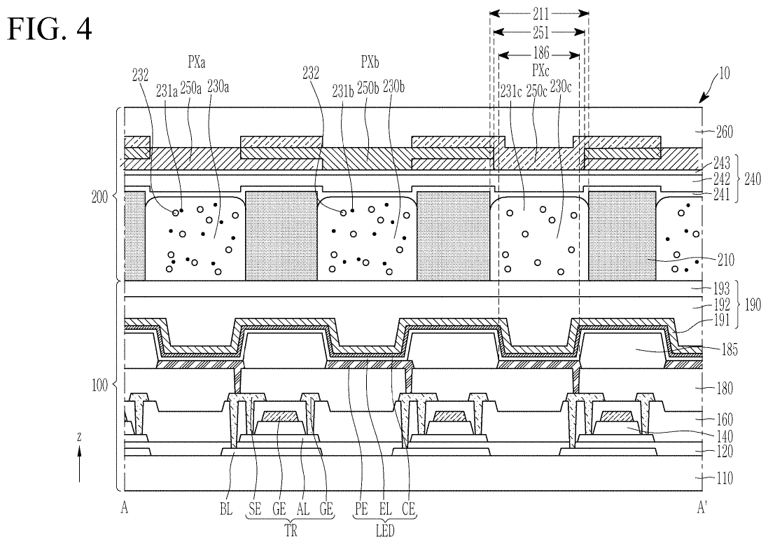

FIG. 3 is a schematic plan view of a display area in a display panel according to some embodiments, and FIG. 4 is a cross-sectional view taken along the line A-A′ in FIG. 3.

Referring to FIG. 3, a plurality of pixels PXa, PXb, PXc are arranged in the display area DA. The pixels PXa, PXb, PXc may include a first pixel PXa, a second pixel PXb, and a third pixel PXc that display different colors. For example, the first pixel PXa may emit red light, the second pixel PXb may emit green light, and the third pixel PXc may emit blue light. In the display area DA, the first pixel PXa, the second pixel PXb, and the third pixel PXc may be repeatedly arranged in the first direction x and the second direction y.

Here, the second pixel PXa may have a light emitting region that is chamfered in a rectangular shape having a pair of long sides L extending in the first direction x and a pair of short sides S extending in the second direction y. Here, a chamfered length of the short side S may be longer than a chamfered length of the long side L. Additionally, the light emitting region may have rounded corners.

The long side L includes a first side L1 defining the light emitting region and a second side L2 which is virtually chamfered. The short side S includes a third side S1 defining the light emitting region and a fourth side S2 which is virtually chamfered. As mentioned above, a length of the fourth side S2 may be longer than a length of the second side L2.

The first pixel PXa may have a light emitting region that is chamfered in a square shape having a pair of sides extending in the first direction x and a pair of sides extending in the second direction y. An angle (θ) between a chamfered corner and the side extending in the first direction x may be 45 degrees. The third pixel PXc may have a light emitting region of the same shape as the first pixel PXa. Additionally, the emitting area may have rounded corners.

The light emitting regions of the first pixel PXa, the second pixel PXb, and the third pixel PXc may be defined by a filter opening 251 described later.

Referring to FIGS. 3 and 4, the display panel 10 may include a display unit (or display) 100 and a color conversion unit 200. The color conversion unit (or color converter or color conversion circuit or color conversion component) 200 may be positioned on the display unit 100, and the color conversion unit 200 may entirely overlap the display unit 100.

The display unit 100 may include light emitting diodes LED corresponding to each pixel PXa, PXb, PXc. The color conversion unit 200 may convert the wavelength of light emitted from the light emitting diode LED and emit it outside the display panel 10.

The display unit 100 may basically include a substrate 110, a transistor TR formed on the substrate 110, and the light emitting diode LED connected to the transistor TR.

The substrate 110 may include a material having rigid properties such as glass, or a material having flexible properties such as plastic. For example, the substrate 110 may be a glass substrate.

A light blocking layer BL may be positioned on the substrate 110. The light blocking layer BL may prevent or reduce instances or amounts of external light reaching a semiconductor layer AL of the transistor TR and thereby prevent or reduce degradation of characteristics of the semiconductor layer AL. A leakage current of the transistor TR, especially a driving transistor which current characteristics are important in light emitting display devices, may be controlled by the light blocking layer BL. The light blocking layer BL may include a material that does not transmit light of a wavelength to be blocked. For example, the light blocking layer BL may include a metal such as copper (Cu), aluminum (Al), molybdenum (Mo), titanium (Ti), or tungsten (W), and may be a single layer or multiple layers. For example, the light blocking layer BL may have a double-layer structure such as titanium (Ti)/copper (Cu). The light blocking layer BL may function as an electrode that receives a specific voltage from the display panel 10. In this case, the current change rate in the saturation region of a voltage-current characteristic graph of the transistor TR is reduced, so that characteristics as the driving transistor may be relatively improved.

A buffer layer 120 may be positioned on the substrate 110 and the light blocking layer BL. The buffer layer 120 may block impurities from the substrate 110 when forming the semiconductor layer AL to relatively improve the characteristics of the semiconductor layer AL and may alleviate stress in the semiconductor layer AL by flattening the surface of the substrate 110. The buffer layer 120 may include an inorganic insulating material such as silicon nitride SiNx, silicon oxide SiOx, or silicon nitride SiOxNy. Additionally, the buffer layer 120 may include amorphous silicon.

The semiconductor layer AL may be positioned on the buffer layer 120. The semiconductor layer AL may include a first region, a second region, and a channel region between the first region and the second region. The semiconductor layer AL may include an oxide semiconductor. For example, the semiconductor layer AL may include the oxide semiconductor, such as indium-gallium-zinc oxide IGZO, which includes at least one of zinc (Zn), indium (In), gallium (Ga), tin (Sn), or mixtures thereof. Additionally, the semiconductor layer AL may include polycrystalline silicon or amorphous silicon, and may include, for example, low-temperature polysilicon LTPS.

A gate insulating layer 140 may be positioned on the semiconductor layer AL. The gate insulating layer 140 may be formed in an area overlapping the gate electrode GE. This structure may be formed by etching the gate insulating layer 140 during a photolithography process for forming the gate electrode GE. Alternatively, it may be formed to substantially cover the entire substrate 110. The gate insulating layer 140 may include an inorganic insulating material such as silicon oxide, silicon nitride, or silicon nitride, and may be a single layer or multiple layers.

The gate electrode GE may be positioned on the gate insulating layer 140. The gate electrode GE may overlap with the channel region of the semiconductor layer AL. The gate electrode GE may include a metal such as molybdenum (Mo), aluminum (Al), copper (Cu), or titanium (Ti), and may be a single layer or multiple layers. For example, the gate electrode GE may have a double-layer structure such as titanium (Ti)/copper (Cu). The first gate line GL1 and/or the second gate line GL2 described above may be in the same layer as the gate electrode GE. In this specification, being formed of the same layer or same layer may mean that the components are formed of a same material in a same process (e.g., the same photolithography process).

An interlayer insulating layer 160 may be positioned on the gate electrode GE. The interlayer insulating layer 160 may include an inorganic insulating material such as silicon oxide, silicon nitride, or silicon oxynitride, and may be a single layer or multiple layers.

A first electrode SE and a second electrode DE of the transistor TR may be positioned on the interlayer insulating layer 160. One of the first electrode SE and the second electrode DE may be a source electrode of the transistor TR and the other may be a drain electrode of the transistor TR. The first electrode SE and the second electrode DE may be connected to the first region and the second region of the semiconductor layer AL, respectively, through contact holes formed in the interlayer insulating layer 160. The first electrode SE or the second electrode DE may be connected to the light blocking layer BL through a contact hole formed in the interlayer insulating layer 160, the gate insulating layer 140, and the buffer layer 120. The first electrode SE and the second electrode DE may include a metal such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu), and may be a single layer or multiple layers. For example, the first electrode SE and the second electrode DE may have a double-layer structure such as titanium (Ti)/copper (Cu), or a triple-layer structure such as titanium (Ti)/aluminum (Al)/titanium (Ti).

The data line DL, the driving voltage line VL1, the common voltage line VL2, the initialization voltage line VL3, the driving voltage transmission line DVL and/or the common voltage transmission line CVL described above may be in the same layer as the first electrode SE and the second electrode DE.

The semiconductor layer AL, the gate electrode GE, the first electrode SE, and the second electrode DE may form the transistor TR. The illustrated transistor TR may correspond to the first transistor T1 in the pixel PX of FIG. 2.

A planarization layer 180 may be positioned on the first electrode SE, the second electrode DE and the interlayer insulating layer 160. The planarization layer 180 may include an organic insulating material such as a general-purpose polymer such as poly(methyl methacrylate) or polystyrene, a polymer derivative having a phenol group, an acrylic polymer, an imide polymer (e.g., polyimide), or a siloxane polymer.

The pixel electrode PE of the light emitting diode LED may be positioned on the planarization layer 180. The pixel electrode PE may be connected to the second electrode DE through a contact hole formed in the planarization layer 180. The pixel electrode PE may be formed of a reflective conductive material or a semi-transparent conductive material, or may be formed of a transparent conductive material. The pixel electrode PE may include a transparent conductive material such as indium tin oxide ITO or indium zinc oxide IZO. The pixel electrode PE may include a metal such as lithium (Li), calcium (Ca), aluminum (Al), silver (Ag), magnesium (Mg), or gold (Au). The pixel electrode PE may have a multilayer structure—for example, a triple-layer structure such as ITO/silver (Ag)/ITO.

A pixel defining layer 185 having a pixel opening 186 overlapping the pixel electrode PE may be positioned on the planarization layer 180. The pixel defining layer 185 may include an organic insulating material such as an acrylic polymer, an imide polymer, or an amide polymer. The pixel defining layer 185 may include a colored pigment, such as a black pigment, a blue pigment, etc. For example, the pixel defining layer 185 may include a polyimide binder and a mixture of red, green, and blue pigments. The pixel defining layer 185 may include a cardo binder resin and a mixture of lactam black pigment and blue pigment. The pixel defining layer 185 may include carbon black. The pixel defining layer 185 containing a black pigment may relatively improve the contrast ratio and prevent or reduce reflection by an underlying metal layer.

The light emitting layer EL may be positioned on the pixel electrode PE and the pixel defining layer 185. The light emitting layer EL may contact the pixel electrode PE through the pixel opening 186. Contrary to what is shown, the light emitting layer EL may also be located within the pixel opening 186. The light emitting layer EL may include a luminescent material that emits blue light. The light emitting layer EL may include a luminescent material that emits red light or green light in addition to blue light. In addition to the light emitting layer EL, at least one of a hole injection layer, a hole transport layer, an electron transport layer, or an electron injection layer may be positioned on the pixel electrode PE.

The common electrode CE may be positioned above the light emitting layer EL. The common electrode CE may be positioned across the pixels PXa, PXb, PXc. The common electrode CE may include a metal such as calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), or lithium (Li). The common electrode CE may include a transparent conductive oxide such as indium tin oxide ITO or indium zinc oxide IZO.

The pixel electrode PE, the light emitting layer EL and the common electrode CE may form the light emitting diode LED, which may be an organic light emitting diode. Pixel electrodes PE are individually provided for each pixel PXa, PXb, PXc so that the driving current may be applied. The common electrode CE may be commonly connected to the pixels PXa, PXb, PXc to receive a common voltage. The pixel electrode PE may be the anode, which is a hole-injecting electrode, and the common electrode CE may be the cathode, which is an electron-injecting electrode, or vice versa.

A display encapsulation layer 190 (hereinafter simply referred to as a first encapsulation layer) may be positioned on the common electrode CE. The first encapsulation layer 190 may seal light emitting diodes LED and prevent or reduce contaminants such as moisture or oxygen penetrating from the outside. The first encapsulation layer (190) covers the entire display area DA, and the edge of the first encapsulation layer (190) may be located in the non-display area NA. The first encapsulation layer 190 may be a thin-film encapsulation layer including a first inorganic layer 191, a second inorganic layer 193, and an organic layer 192. The organic layer 192 may be located between the first inorganic layer 191 and the second inorganic layer 193. The first inorganic layer 191 and the second inorganic layer 193 may mainly prevent or reduce the penetration of contaminants such as moisture, etc., and the organic layer 192 may mainly flatten the surface of the first encapsulation layer 190, particularly the surface of the second inorganic layer 193 in the display area DA. The first inorganic layer 191 and the second inorganic layer 193 may include an inorganic insulating material such as silicon oxide or silicon nitride. The organic layer 192 may include an organic material such as acrylic resin, methacrylic resin, polyisoprene, vinyl resin, epoxy resin, urethane resin, cellulose resin, or perylene resin.

The color conversion unit 200 may include a bank 210, a reflective layer 220, first and second color conversion layers 230a, 230b, a transparent layer 230c, a color conversion unit encapsulation layer 240, color filters 250a, 250b, 250c, and an overcoat layer 260.

The bank 210 may be positioned on the first encapsulation layer 190 of the display unit 100. For example, a lower surface of the bank 210 may be in contact with an upper surface of the first encapsulation layer 190. The bank 210 may overlap with the pixel defining layer 185. The bank (210) may not overlap or may have little overlap with the light emitting diode LED. The bank (210) may be located at a boundary of the pixels PXa, PXb, PXc.

The bank 210 may include a bank opening 211 that overlaps the light emitting diode LED. The bank opening 211 may penetrate the bank 210 in the third direction (z). the first color conversion layer 230a may be positioned in the bank opening 211 of the first pixel PXa, and the second color conversion layer 230b may be positioned in the bank opening 211 of the second pixel PXb. Additionally, the transparent layer 230c may be positioned in the bank opening 211 of the third pixel PXc. The bank opening 211 may overlap with the pixel opening 186.

Lower surfaces of the first color conversion layer 230a, the second color conversion layer 230b, and the transparent layer 230c may be in contact with the upper surface of the first encapsulation layer 190. The first color conversion layer 230a, the second color conversion layer 230b, and the transparent layer 230c may be formed by an inkjet printing process.

The first color conversion layer 230a may overlap with the light emitting diode LED corresponding to the first pixel PXa and may convert light incident from the light emitting diode LED into light of a first wavelength. The light of the first wavelength may be red light having a maximum emission peak wavelength in a range of 600 nanometers (nm) to 650 nm (or about 600 nm to about 650 nm)—for example, 620 nm to 650 nm (or about 620 nm to about 650 nm).

The second color conversion layer 230b may overlap with the light emitting diode LED corresponding to the second pixel PXb and may convert light incident from the light emitting diode LED into light of a second wavelength. The light of the second wavelength may be green light having a maximum emission peak wavelength in a range of 500 nm to 550 nm (or about 500 nm to about 550 nm)—for example, 510 nm to 550 nm (or about 510 nm to about 550 nm).

The transparent layer 230c may overlap with the light emitting diode LED corresponding to the third pixel PXc and may transmit light incident from the light emitting diode LED. The light transmitted through the transmission layer 230c may be light of a third wavelength. The light of the third wavelength may be blue light having a maximum emission peak wavelength in a range of 380 nm to 480 nm (or about 380 nm to about 480 nm)—for example, greater than or equal to 420 nm (or about 420 nm), greater than or equal to 430 nm (or about 430 nm), greater than or equal to 440 nm (or about 440 nm), greater than or equal to 445 nm (or about 445 nm), less than or equal to 470 nm (or about 470 nm), less than or equal to 460 nm (or about 460 nm), or less than or equal to 450 nm (or about 455 nm).

The first color conversion layer 230a and the second color conversion layer 230b may each include first quantum dots 231a and second quantum dots 231b. For example, light incident on the first color conversion layer 230a may be converted into light of the first wavelength by the first quantum dots 231a and emitted. Light incident on the second color conversion layer 230b may be converted into light of the second wavelength by the second quantum dots 231b and emitted. The first color conversion layer 230a, the second color conversion layer 230b, and the transparent layer 230c may include scatterers 232. The scatterers 232 may relatively improve light efficiency by scattering light incident on the first color conversion layer 230a, the second color conversion layer 230b, and the transmission layer 230c.

The scatterers 232 may be metal oxide particles and/or organic particles. Metal oxides include TiO₂, ZrO₂, Al₂O₃, In₂O₃, ZnO, SnO₂, etc. Examples of materials for organic particles include acrylic resins and urethane resins. The scatterers 232 may scatter light in a random direction regardless of the direction in which the incident light is incident.

The first quantum dot 231a and the second quantum dot 231b (hereinafter, also referred to as a quantum dot or a semiconductor nanocrystal) may each independently include a group II-VI compound, a group III-V compound, a group IV-VI compound, a group IV element or compound, a group I-III-VI compound, a group II-III-VI compound, a group I-II-IV-VI compound, or a combination thereof.

The group II-VI compound is a binary compound selected from the group consisting of CdSe, CdTe, ZnS, ZnSe, ZnTe, ZnO, HgS, HgSe, HgTe, MgSe, MgS and mixtures thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof; and a group consisting of quaternary compounds selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof. Group II-VI compounds may further contain group III metals.

The group III-V compound may be selected from the group consisting of binary compounds selected from the group consisting of GaN, GaP, GaAs, GaSb, AlN, AlP, AlAs, AlSb, InN, InP, InAs, InSb, and mixtures thereof; ternary compounds selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InZnP, InPSb, and mixtures thereof; and quaternary compounds selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof. Group III-V compounds may further contain group II metals (e.g., InZnP).

The group IV-VI compound may be selected from the group consisting of binary compounds selected from the group consisting of SnS, SnSe, SnTe, PbS, PbSe, PbTe and mixtures thereof; ternary compounds selected from the group consisting of SnSeS, SnSeTe, SnSTe, PbSeS, PbSeTe, PbSTe, SnPbS, SnPbSe, SnPbTe and mixtures thereof; and quaternary compounds selected from the group consisting of SnPbSSe, SnPbSeTe, SnPbSTe and mixtures thereof.

The group IV element or compound may be selected from the group consisting of a monoatomic compound selected from the group consisting of Si, Ge and combinations thereof; and a binary compound selected from the group consisting of SiC, SiGe and combinations thereof.

The group I-III-VI compounds may be selected from CuInSe2, CuInS2, CuInGaSe and CuInGaS.

The group II-III-VI compound may be selected from the group consisting of ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe and combinations thereof.

The group I-II-IV-VI compounds may be selected from CuZnSnSe and CuZnSnS.

Quantum dots may be cadmium-free. Quantum dots may include semiconductor nanocrystals based on group III-V compounds including indium and phosphorus. Group III-V compounds may further contain zinc. Quantum dots may include semiconductor nanocrystals based on group II-VI compounds including chalcogen elements (e.g., sulfur, selenium, tellurium, or combinations thereof) and zinc.

In quantum dots, the aforementioned binary, ternary and/or quaternary compounds may exist within the particle at a uniform concentration, or may exist within the same particle in a state where the concentration distribution is partially divided into different states. Additionally, one quantum dot may have a core/shell structure surrounding another quantum dot. A interface between a core and a shell may have a concentration gradient in which the concentration of elements present in the shell decreases toward a center.

In some embodiments, the quantum dots may have a core-shell structure including a core comprising the aforementioned nanocrystals and a shell surrounding the core. The shell of the quantum dot may serve as a protective layer to maintain semiconductor properties by preventing or reducing chemical modification of the core and/or as a charging layer to impart electrophoretic properties to the quantum dot. The shell may be single-layered or multi-layered. The interface between the core and the shell may have a concentration gradient in which the concentration of elements present in the shell decreases toward the center. Examples of shells of quantum dots include oxides of metals or non-metals, semiconductor compounds, or combinations thereof.

The oxides of metals or nonmetals may be binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, or ternary compounds such as MgAl₂O₄, CoFe₂O₄, NiFe₂O₄, CoMn₂O₄.

Semiconductor compounds include, but are not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc.

Quantum dots may have a full width of half maximum of an emission wavelength spectrum in a range of 45 nm (or about 45 nm) or less, 40 nm (or about 40 nm) or less, or 30 nm (or about 30 nm) or less, and may relatively improve color purity or color reproducibility in this range. Additionally, since the light emitted by these quantum dots is emitted in all directions, the viewing angle may be relatively improved.

Quantum dots may have shell materials and core materials with different energy band gaps. For example, the energy band gap of the shell material may be larger or smaller than that of the core material. Quantum dots may have multilayer shells. In the multilayer shell, the energy band gap of the outer layers may be larger than that of the inner layers (i.e., the layers closer to the core). In the multilayer shell, the energy band gap of the outer layer may be smaller than the energy band gap of the inner layer.

A shape of the quantum dots is not particularly restricted. For example, the shape of the quantum dot may include a sphere, a polyhedron, a pyramid, a multipod, a square, a cuboid, a nanotube, a nanorod, a nanowire, a nanosheet, or a combination thereof.

Quantum dots may include organic ligands (e.g., having hydrophobic moieties and/or hydrophilic moieties). Organic ligand moieties may be bound to the surface of quantum dots. The organic ligand may include RCOOH, RNH₂, R₂NH, R₃N, RSH, R₃PO, R₃P, ROH, RCOOR, RPO(OH)₂, RHPOOH, R₂POOH, or combinations thereof. Here, R may each independently be a substituted or unsubstituted aliphatic hydrocarbon group having a carbon number of C3 to C40 (e.g., C5 or more and C24 or less), a substituted or unsubstituted alkenyl group, a substituted or unsubstituted aromatic hydrocarbon group having a carbon number of C6 to C40 (e.g., C6 or more and C20 or less), or a combination thereof.

Examples of organic ligands include thiol compounds such as methanethiol, ethanethiol, propanethiol, butanethiol, pentanethiol, hexanethiol, octanethiol, dodecanethiol, hexadecanethiol, octadecanethiol, and benzylthiol; amines such as methane amine, ethane amine, propan amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributyl amine, and trioctyl amine; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and benzoic acid; phosphine compounds such as methyl phosphine, ethyl phosphine, propyl phosphine, butyl phosphine, pentyl phosphine, octyl phosphine, dioctyl phosphine, tributyl phosphine, and trioctyl phosphine; phosphine compounds such as methyl phosphine oxide, ethyl phosphine oxide, propyl phosphine oxide, butyl phosphine oxide, pentyl phosphine oxide, tributylphosphine oxide, octylphosphine oxide, dioctyl phosphine oxide, and trioctylphosphine oxide, or oxide compounds thereof; diphenyl phosphine, triphenyl phosphine compounds, or oxide compounds thereof; examples thereof include C5 to C20 alkyl phosphinic acids, C5 to C20 alkyl phosphonic acids, such as hexylphosphinic acid, octylphosphinic acid, dodecane phosphinic acid, tetradecane phosphinic acid, hexadecane phosphinic acid, and octadecane phosphinic acid; and the like. Quantum dots may contain hydrophobic organic ligands alone or in a mixture of one or more. The hydrophobic organic ligand may not contain a photopolymerizable moiety (e.g., an acrylate group, a methacrylate group, etc.).

The color conversion encapsulation layer 240 (hereinafter referred to simply as a second encapsulation layer) may be positioned on the bank 210, the first and second color conversion layers 230a, 230b, and the transparent layer 230c. The second encapsulation layer 240 may seal the first and second color conversion layers 230a, 230b and the transparent layer 230c. The second encapsulation layer 240 may be a thin-film encapsulation layer including a first inorganic layer 241, an organic layer 242, and a second inorganic layer 243. The organic layer 242 may be located between the first inorganic layer 241 and the second inorganic layer 243. The first inorganic layer 241 and the second inorganic layer 243 may mainly prevent or reduce the penetration of moisture, etc., and the organic layer 242 may mainly flatten the surface of the second encapsulation layer 240, particularly the surface of the second inorganic layer 243. The first inorganic layer 241 and the second inorganic layer 243 may include an inorganic insulating material such as silicon oxide or silicon nitride. The organic layer 242 may include an organic material such as acrylic resin, methacrylic resin, polyisoprene, vinyl resin, epoxy resin, urethane resin, cellulose resin, or perylene resin.

At least one of the first inorganic layer 241, the organic layer 242, or the second inorganic layer 243 may be a low-refractive index layer. For example, the organic layer 242 may be a low-refractive index layer, and the organic layer 242 may include an organic material having a low refractive index. The refractive index of the low-refractive index layer may be in a range of 1.1 to 1.3 (or about 1.1 to about 1.3).

The color filters 250a, 250b, 250c may be positioned on the second encapsulation layer 240. The color filters 250a, 250b, 250c may overlap the pixel opening 186 and the bank opening 211. The color filters 250a, 250b, 250c may include the first color filter 250a that transmits light of the first wavelength and absorbs light of the remaining wavelengths, the second color filter 250b that transmits light of the second wavelength and absorbs light of the remaining wavelengths, and the third color filter 250c that transmits light of the third wavelength and absorbs light of the remaining wavelengths.

At the boundaries of the pixels PXa, PXb, PXc, the first color filter 250a, the second color filter 250b, and the third color filter 250c may overlap each other to form a light blocking region. The light blocking region may overlap with the bank 210 and the pixel defining layer 185, and the filter opening 251 is formed between the light blocking regions to define the light emitting region of each pixel PXa, PXb, PXc. Additionally, the filter opening 251 may overlap with the bank opening 211 and the pixel opening 186. A width of the bank opening 211 may be greater than a width of the filter opening 251, and the width of the filter opening 251 may be greater than a width of the pixel opening 186. Additionally, without limitation thereto, the width of the filter opening 251 may be equal to the width of the bank opening 211 and the width of the pixel opening 186.

The first color filter 250a, the second color filter 250b, and the third color filter 250c positioned in the filter opening 251 may overlap the first color conversion layer 230a, the second color conversion layer 230b, and the transparent layer 230c, respectively. The first color filter 250a, the second color filter 250b, and the third color filter 250c may correspond to the first pixel PXa, the second pixel PXb, and the third pixel PXc, respectively. Accordingly, a purity of light of the first wavelength (corresponding to the first pixel PXa), light of the second wavelength (corresponding to the second pixel PXb), and light of the third wavelength (corresponding to the third pixel PXb) emitted outside the display panel 10 may be increased. The light of the first wavelength, the light of the second wavelength, and the light of the third wavelength may be red light, green light, and blue light, respectively.

As illustrated, the first color filter 250a, the second color filter 250b, and the third color filter 250c may all overlap to form a light blocking region, but two color filters may also overlap to form the light blocking region. For example, the first color filter 250a and the second color filter 250b may overlap at the boundary between the first pixel PXa and the second pixel PXb, the second color filter 250b and the third color filter 250c may overlap at the boundary between the second pixel PXb and the third pixel PXc, and the third color filter 250c and the first color filter 250a may overlap at the boundary between the third pixel PXc and the first pixel PXa. The first color filter 250a, the second color filter 250b, and the third color filter 250c are stacked in that order on the second encapsulation layer 240, but they may be stacked in a different order. Instead of overlapping color filters 250a, 250b, 250c, the light blocking region may be provided by forming a light blocking member including a black pigment or dye.

The overcoat layer 260 may be positioned on the color filters 250a, 250b, 250c. The overcoat layer may include an inorganic insulating material and/or an organic insulating material, and may be a single layer or multiple layers. An anti-reflection layer that relatively reduces external light reflection may be positioned on the overcoat layer 260.

In general, in the case of the display panel 10 including the color conversion unit 200 to which the first quantum dots 231a, the second quantum dots 231b, and the scatterers 232 are applied, the diffuse reflectance SCE due to external light may be high. However, according to some embodiments, the corners of the light emitting region, which have a relatively small amount of light emission, may be chamfered to minimize the decrease in light emission efficiency while reducing the diffuse reflectance.

Meanwhile, in these embodiments, it has been stated that the display panel 10 includes one substrate 110 and the color conversion unit 200 is formed on the display unit 100, but it is not limited thereto, and the display panel 10 may include two substrates. In this case, the color conversion unit 200 may be formed on a separate substrate and joined to the display unit 100.

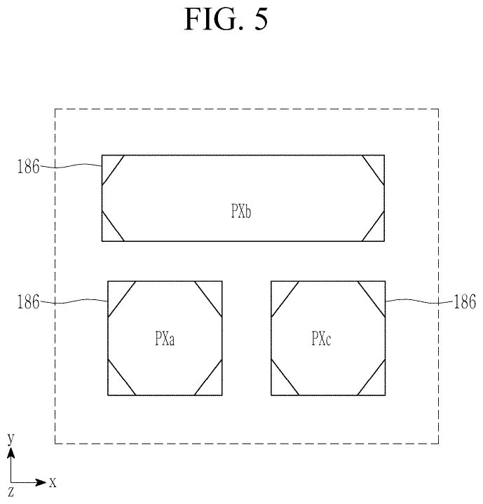

Meanwhile, according to some embodiments, when chamfering the light emitting region of the pixel, both the filter opening defining the light emitting region and the bank opening and the pixel opening overlapping therewith are chamfered, but this is not limited thereto. For example, as illustrated in FIG. 5, which is a schematic plan view of a display area in a display panel according to some embodiments of the present disclosure, the pixel opening 186 of each pixel PXa, PXb, PXc may not be chamfered.

That is, in the second pixel PXb, the light emitting region may be a chamfered shape in a rectangular shape having a pair of long sides extending in the first direction x and a pair of short sides extending in the second direction y, and the pixel opening 186 may be a rectangular shape having a pair of long sides extending in the first direction x and a pair of short sides extending in the second direction. In the first pixel PXa, the light emitting region may have a square shape or a chamfered shape, and the pixel opening 186 may have a square shape. The third pixel PXc may have a light emitting region and pixel opening 186 of the same shape as the first pixel PXa. The remaining structure may be identical to the structure of the display device according to FIGS. 1 to 4.

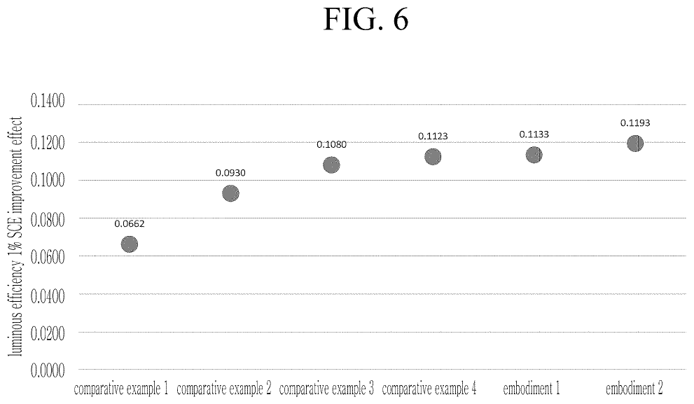

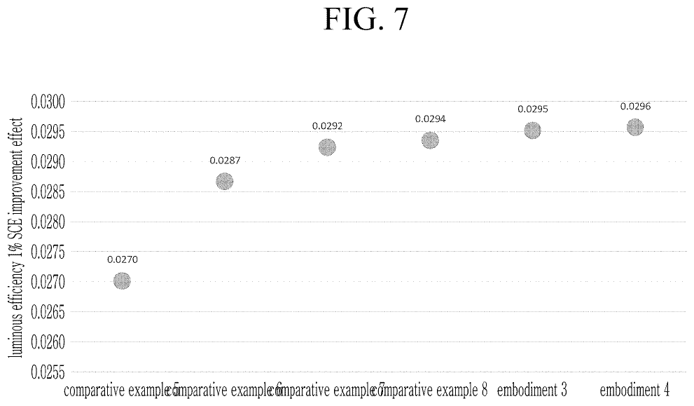

FIGS. 6 and 7 are graphs showing the reflectance improvement effect per 1% of luminous efficiency of a display device according to some embodiments and a display device according to some embodiments.

In FIG. 6, a display device according to some embodiments and a display device according to some embodiments include a pixel having a light emitting region having a chamfered shape in a rectangular shape having a pair of long sides extending in the first direction x and a pair of short sides extending in the second direction y.

The display device according to embodiment 1 has a light emitting region in which a pixel has a chamfered length of 7 on the long side and a chamfered length of 12 on the short side. A display device according to embodiment 2 has a light emitting region in which a pixel has a chamfered length of 5 on the long side and a chamfered length of 16 on the short side. The display device according to embodiment 1 has a light emitting region having a chamfered length of 27 on the long side and a chamfered length of 3 on the short side. The display device according to embodiment 2 has a light emitting region having a chamfered length of 16 on the long side and a chamfered length of 5 on the short side. The display device according to embodiment 3 has a light emitting region having a chamfered length of 12 on the long side and a chamfered length of 7 on the short side. The display device according to embodiment 4 has a light emitting region having a chamfered length of 9 on the long side and a chamfered length of 9 on the short side.

As may be seen in FIG. 6, in the case of display devices including pixels having a light emitting region in which the chamfered length of the short side is longer than that of the long side (embodiments 1 and 2), the diffuse reflectance SCE effect per 1% of luminous efficiency is greater than in the case of display devices including pixels having a light emitting region in which the chamfered length of the short side is shorter than or equal to that of the long side (comparative examples 1 to 4).

In FIG. 7, a display device according to some embodiments and a display device according to some embodiments includes a pixel having a light emitting region having a chamfered shape in a rectangular shape having a pair of long sides extending in the first direction x and a pair of short sides extending in the second direction y. Here, the pixel opening is a non-chamfered structure. That is, the pixel opening is a rectangular shape having a pair of long sides extending in the first direction x and a pair of short sides extending in the second direction y.

The display device according to embodiment 3 has a light emitting region in which a pixel has a chamfered length of 7 on the long side and a chamfered length of 12 on the short side. The display device according to embodiment 4 has a light emitting region in which a pixel has a chamfered length of 5 on the long side and a chamfered length of 16 on the short side. The display device according to embodiment 5 has a light emitting region having a chamfered length of 27 on the long side and a chamfered length of 3 on the short side. The display device according to embodiment 6 has a light emitting region having a chamfered length of 16 on the long side and a chamfered length of 5 on the short side. The display device according to embodiment 7 has a light emitting region having a chamfered length of 12 on the long side and a chamfered length of 7 on the short side. The display device according to embodiment 8 has a light emitting region having a chamfered length of 9 on the long side and a chamfered length of 9 on the short side.

As may be seen in FIG. 7, in the case of display devices including pixels having a light emitting region in which the chamfered length of the short side is longer than that of the long side (embodiments 3 and 4), it may be seen that the diffuse reflectance SCE effect per 1% of luminous efficiency is greater than in the case of display devices including pixels having a light emitting region in which the chamfered length of the short side is shorter or equal to that of the long side (comparative examples 5 to 8).

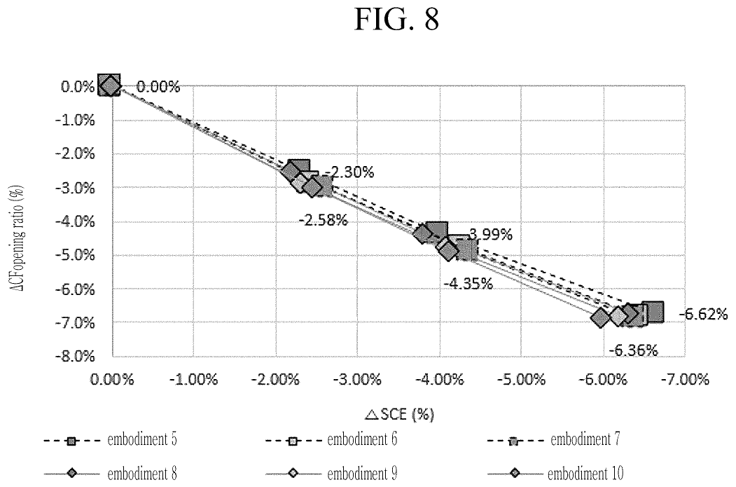

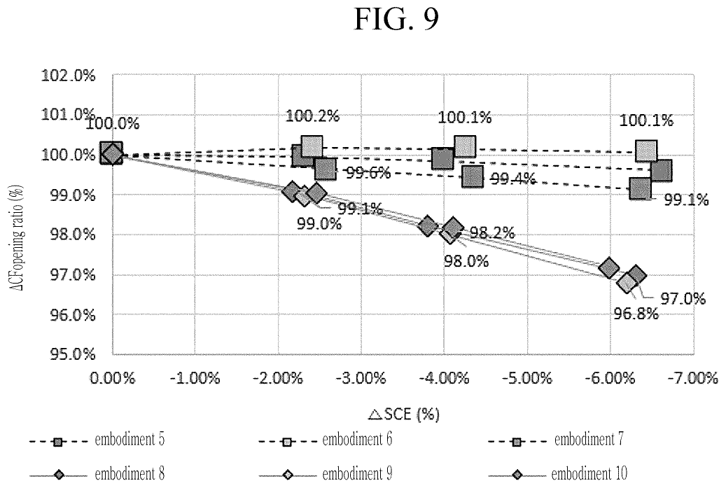

FIG. 8 is a graph showing a change in reflectivity according to a decrease in the aperture ratio of the field aperture of a display device according to some embodiments. FIG. 9 is a graph showing luminous efficiency according to a decrease in the reflectivity of a display device according to some embodiments.

In FIGS. 8 and 9, the display devices according to embodiments 5 to 7 include pixels having a light emitting region having a chamfered shape in a rectangular shape having a pair of long sides extending in the first direction x and a pair of short sides extending in the second direction y.

The display device according to embodiments 8 to 10 includes a pixel having a light emitting region having a chamfered shape in a rectangular shape having a pair of long sides extending in a first direction x and a pair of short sides extending in a second direction y. Here, the pixel opening is a non-chamfered structure. That is, the pixel opening is a rectangular shape having a pair of long sides extending in the first direction x and a pair of short sides extending in the second direction y.

Additionally, the display devices according to embodiments 5 and 8 have pixels of 109 ppi, the display devices according to embodiments 6 and 9 have pixels of 59 ppi, and the display devices according to embodiments 7 and 10 have pixels of 140 ppi.

As may be seen in FIG. 8, the display device according to some embodiments has a reflectivity that is reduced by 6.5% (or about 6.5%) when the aperture ratio of the field aperture is reduced by 7% (or about 7%). In addition, as may be confirmed in FIG. 9, it may be seen that the display device according to some embodiments has a luminous efficiency that decreases by 4% (or about 4%) or less when the reflectivity decreases by 7% (or about 7%).

That is, it may be seen that the display device according to some embodiments may reduce the reflectivity while minimizing the decrease in luminous efficiency by including a pixel having a chamfered light emitting region in a rectangular shape having a pair of long sides extending in the first direction x and a pair of short sides extending in the second direction y.

The display device described above may be applied to a variety of electronic devices. The electronic device according to some embodiments may include the display device described above and may further include modules or devices having other additional functions in addition to the display devices.

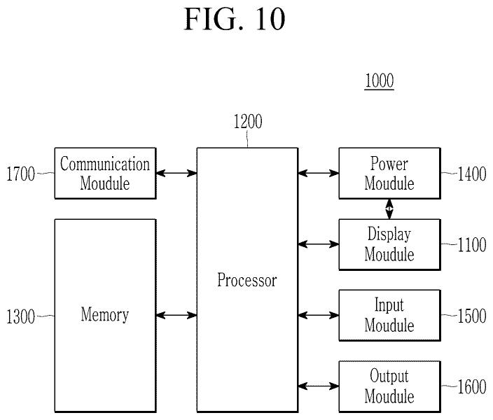

FIG. 10 is a block diagram of the electronic device according to some embodiments. Referring to FIG. 10, the electronic device 1000 may include a display module 1100, a processor 1200, a memory 1300, and a power module 1400. The electronic device 1000 may further include an input module 1500, a non-image output module 1600, and/or a communication module 1700.

The electronic device 1000 may output various information in the form of an image via the display module 1100. When the processor 1200 executes an application stored in the memory 1300, the display module 1100 may provide the user with the visual information provided by the application. The power module 1400 may include a power supply module, such as a power adapter or battery unit, and a power conversion module that converts the power supplied by the power supply module to generate the power required for operation of the electronic device 1000. The input module 1500 may provide input information to the processor 1200 and/or the display module 1100. The non-image output module 1600 may receive non-image information from the processor 1200. Such as sound, haptic, light or other information, and provide it to users. The communication module 1700 is a module responsible for sending and receiving information between the electronic device 1000 and an external device, and may include a receiving part and a transmitting part.

At least one of each of the above-described configurations of the electronic device 1000 may be included within the display device according to the above-described embodiments. Additionally, some of modules that are functionally included within a single module may be included within the display device and others may be provided separately from the display device. For example, the display device may include the display module 1100, and a processor 1200, memory 1300, and power module 1400 may be provided in the form of other devices within the electronic device 1000 other than the display device.

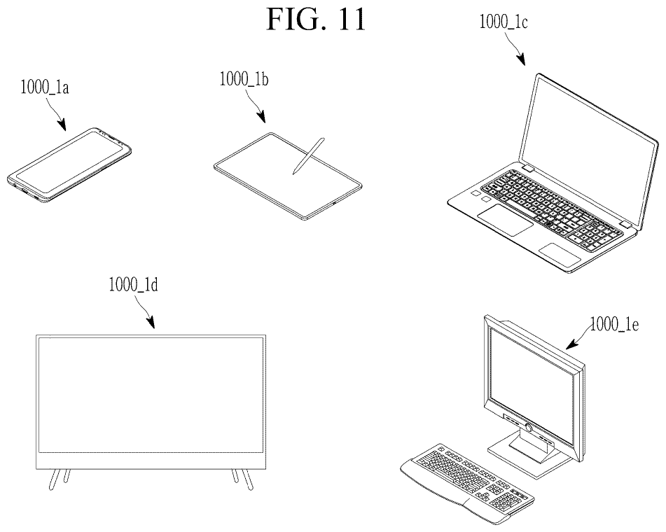

FIGS. 11 to 13 are schematic diagrams of electronic devices according to some embodiments. FIGS. 11 to 13 illustrate examples of various electronic devices with indicating devices according to various embodiments.

FIG. 11 illustrates a smartphone 1000_1a, a tablet PC 1000_1b, a laptop 1000_1c, a television (TV) 1000_1d, and a desk monitor 1000_1e as examples of electronic devices.

The smartphone 1000_1a may include the input module such as a touch sensor and the communication module in addition to the display module 1100. The smartphone 1000_1a may process information received through the communication module or other input module and display the information through the display module of the display device.

The tablet PC 1000_1b, the laptop 1000_1c, the TV 1000_1d, and the desk monitor 1000_1e also may include the display modules and the input modules similar to the smartphone 1000_1a, and in some cases may further include communication modules.

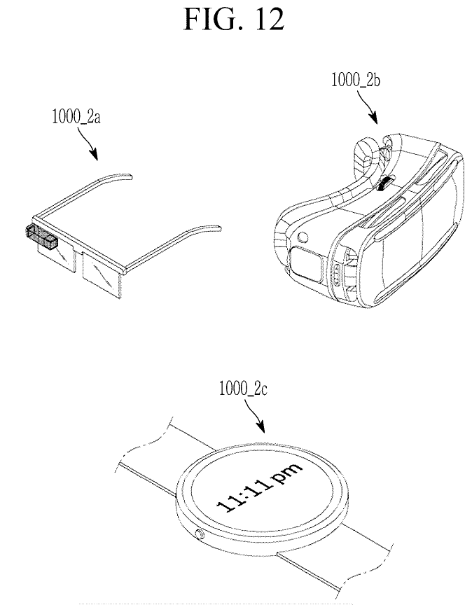

FIG. 12 illustrates an electronic device including the display module applied to a wearable electronic device. The wearable electronic device may include a smart eyewear 1000_2a, a head-mounted display 1000_2b, a smart watch 1000_2c, etc.

The smart glass 1000_2a and the head-mounted display 1000_2b may include the display module that emits a display image and provides it to the user's eyes, thereby providing a virtual reality view or augmented reality view to the user.

The smartwatch 1000_2c may include a biometric sensor as the input device, and may provide biometric information recognized by the biometric sensor to the user through the display module.

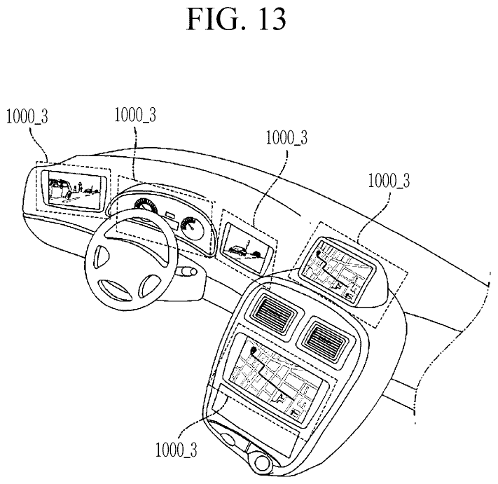

FIG. 13 illustrated an example of the electronic device including the display module applied to a vehicle. For example, the electronic device 1000_3 may be applied to an instrument panel, a center fascia, etc. of the vehicle, or to a center information display (CID) placed on a dashboard of the vehicle, or to a room mirror display that replaces a side mirror.

Although aspects of some embodiments of the present disclosure have been described in detail above, the scope of embodiments according to the present disclosure are not limited thereto, and various modifications and improvements made by those skilled in the art using the basic concepts of the present disclosure defined in the following claims, and their equivalents, are also possible.

Description of Some of the Reference Symbols

| | |
|---|---|
| 1: display device | 10: display panel |
| 100: display unit | 110: substrate |
| 185: pixel defining layer | 186: pixel opening |
| 190: display unit encapsulation layer | 200: color conversion unit |
| 210: bank | 211: bank opening |
| 230a: first color conversion layer | 230b: second color conversion |
| | layer |
| 230c: transparent layer | 231a, 231b: quantum dot |
| 232: scatterer | 240: color conversion unit |
| | encapsulation layer |
| 250a: first color filter | 250b: second color filter |
| 250c: third color filter | 251: filter opening |
| 260: overcoat layer | DA: display area |
| LED: light emitting diode | NA: non-display area |
| PX, PXa, PXb, PXc: pixel | T1, T2, T3, TR: transistor |

What is claimed is:

1. A display device, comprising:
a display panel including a first pixel, a second pixel, and a third pixel, wherein the first pixel includes a first light emitting region,
the second pixel includes a second light emitting region,
the third pixel includes a third light emitting region,
the second light emitting region has a chamfered rectangular shape having a pair of long sides extending in a first direction and a pair of short sides extending in a second direction,
the long side includes a first side defining the second light emitting region and a second side which is virtually chamfered,
the short side includes a third side defining the second light emitting region and a fourth side which is virtually chamfered, and
a length of the fourth side is longer than a length of the second side.

2. The display device of claim 1, wherein:
the first light emitting region has a chamfered square shape having a pair of sides extending in the first direction and a pair of sides extending in the second direction, and
an angle between a chamfered corner and the side extending in the first direction is 45 degrees.

3. The display device of claim 2, wherein:
the display panel further comprises:
a substrate;
a first transistor, a second transistor, and a third transistor on the substrate;
a planarization layer on the first transistor, the second transistor, and the third transistor;
pixel electrodes on the planarization layer and connected to each of the first transistor, the second transistor, and the third transistor;
a pixel defining layer on the planarization layer and having a plurality of pixel openings overlapping the pixel electrodes;
a light emitting layer on the pixel electrodes and the pixel defining layer, and in contact with the pixel electrodes through the pixel openings;
a common electrode on the light emitting layer;
a first encapsulation layer on the common electrode;
a bank positioned on the first encapsulation layer and including a plurality of bank openings, and
a first color conversion layer, a second color conversion layer, and a transparent layer individually positioned within the plurality of bank openings.

4. The display device of claim 3, wherein:
the first color conversion layer and the second color conversion layer include quantum dots and scatterers, and the transparent layer includes scatterers.

5. The display device of claim 4, wherein:
the bank opening overlaps a pixel opening from among the pixel openings.

6. The display device of claim 5, wherein:
the first color conversion layer overlaps a pixel electrode from among the pixel electrodes connected to the first transistor,
the second color conversion layer overlaps the pixel electrode connected to the second transistor, and
the transparent layer overlaps the pixel electrode connected to the third transistor.

7. The display device of claim 6, wherein:
the display panel further comprises:
a second encapsulation layer on the bank, the first color conversion layer, the second color conversion layer and the transparent layer; and
a first color filter, a second color filter, a third color filter, a light blocking region, and a plurality of filter openings on the second encapsulation layer.

8. The display device of claim 7, wherein:
the second encapsulation layer includes a low-refractive index layer.

9. The display device of claim 8, wherein:
the light blocking region is at a boundary of the first pixel, the second pixel and the third pixel, and
overlaps the bank and the pixel defining layer.

10. The display device of claim 9, wherein:
each of the plurality of filter openings defines the first light emitting region, the second light emitting region, and the third light emitting region, and
the first color filter, the second color filter, and the third color filter are each individually positioned within the plurality of filter openings.

11. The display device of claim 10, wherein the light blocking region is formed by overlapping the first color filter, the second color filter, and the third color filter.

12. The display device of claim 11, wherein:
the first color filter overlaps the first color conversion layer,
the second color filter overlaps the second color conversion layer, and
the third color filter overlaps the transparent layer.

13. The display device of claim 12, wherein the filter opening overlaps the bank opening.

14. The display device of claim 13, wherein:
a width of the bank opening is wider than a width of the filter opening, and
the width of the filter opening is wider than a width of the pixel opening.

15. The display device of claim 13, wherein the second pixel includes the pixel opening having a rectangular shape having a pair of long sides extending in the first direction and a pair of short sides extending in the second direction.

16. The display device of claim 15, wherein the first pixel includes the pixel opening having a square shape having a pair of sides extending in the first direction and a pair of sides extending in the second direction.

17. An electronic device, comprising:
a display device including a display panel including a first pixel, a second pixel, and a third pixel;
a processor; and
a power module, wherein
the first pixel includes a first light emitting region,
the second pixel includes a second light emitting region,
the third pixel includes a third light emitting region,
the second light emitting region has a chamfered rectangular shape having a pair of long sides extending in a first direction and a pair of short sides extending in a second direction,
the long side includes a first side defining the second light emitting region and a second side which is virtually chamfered,
the short side includes a third side defining the second light emitting region and a fourth side which is virtually chamfered, and
a length of the fourth side is longer than a length of the second side.

18. The electronic device of claim 17, wherein the electronic device is one of a smartphone, a tablet personal computer (PC), a monitor, a laptop, a television, or a wearable electronic device.
